(19) United States
(12) Patent Application Publication
(10) Pub. No.: US 2008/0061302 A1
(43) Pub. Date: Mar. 13, 2008

(54) LIGHT EMITTING DIODE AND METHOD OF FABRICATING THE SAME

(76) Inventor: Dae Sung Kang, Gwangju-si (KR)

Correspondence Address: BIRCH STEWART KOLASCH & BIRCH, PO BOX 747, FALLS CHURCH, VA, 22040-0747, US

(21) Appl. No.: 11/853,566

(22) Filed: Sep. 11, 2007

(30) Foreign Application Priority Data
Sep. 12, 2006 (KR) 10-2006-0088194

(51) Int. Cl. H01L 33/00

(52) U.S. Cl. 257/75; 438/36; 257/E33.003

(57) ABSTRACT

A light emitting diode comprises an N-type semiconductor layer comprising a horizontal lattice defect layer, an active layer on the N-type semiconductor layer, and a P-type semiconductor layer on the active layer.

The present application claims priority under 35 U.S.C. 119 and 35 U.S.C. 365 to Korean Patent Application No. 10-2006-0088194 (filed on Sep. 12, 2006), which is hereby incorporated by reference in its entirety.

### BACKGROUND

The embodiment relates to a light emitting diode and a method of fabricating the same.

Such a light emitting diode refers to a device that converts an electrical signal in the form of light such as infrared or visible light using characteristics of a compound semiconductor.

The light emitting diode is designed to sequentially form an undoped GaN layer, an N-type semiconductor layer, an active layer, and a P-type semiconductor layer on a substrate, and then to apply power to the N-type and P-type semiconductor layers, so that light is emitted from the active layer.

### SUMMARY

An embodiment provides a light emitting diode in which luminous efficiency is improved and a method of fabricating the same.

An embodiment provides a light emitting diode and a method of fabricating the same, capable of inhibiting dislocation, caused by lattice defects between a substrate and a semiconductor layer, from being propagated.

An embodiment provides a light emitting diode and a method of fabricating the same, in which electrons are more uniformly injected throughout an active layer, thereby improving luminous characteristics.

According to the embodiment, a light emitting diode comprises an N-type semiconductor layer comprising a horizontal lattice defect layer, an active layer on the N-type semiconductor layer, and a P-type semiconductor layer on the active layer.

According to the embodiment, a method of fabricating a light emitting diode, which comprises the steps of forming an N-type semiconductor layer comprising a horizontal lattice defect layer, forming an active layer on the N-type semiconductor layer, and forming a P-type semiconductor layer on the active layer.

### BRIEF DESCRIPTION OF THE DRAWINGS

FIG. 1 is a sectional view for explaining a light emitting diode according to an embodiment; and

FIG. 2 is a flowchart for explaining a method of fabricating a light emitting diode according to an embodiment.

### DETAILED DESCRIPTION OF THE EMBODIMENTS

Hereinafter, a light emitting diode and a method of fabricating the same according to an embodiment will be described in detail with reference to the accompanying drawings.

It will be understood that, when an element is referred to as being “on” or “under” another element, it can be directly on or under the element, and one or more intervening elements may also be present.

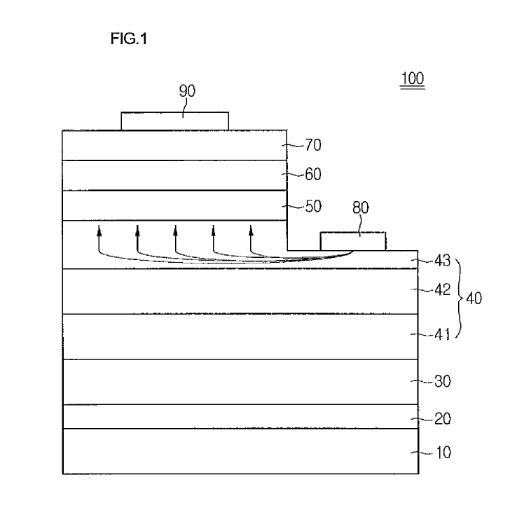

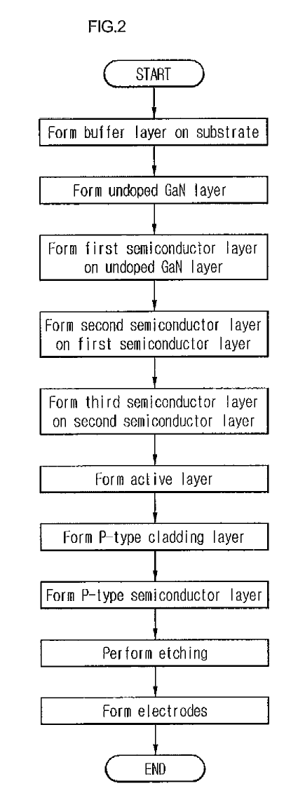

FIG. 1 is a sectional view for explaining a light emitting diode according to an embodiment, and FIG. 2 is a flowchart for explaining a method of fabricating a light emitting diode according to an embodiment.

Referring to FIG. 1, the light emitting diode 100 according to an embodiment comprises a substrate 10, a buffer layer 20, an undoped GaN layer 30, a first semiconductor layer 41, a second semiconductor layer 42, a third semiconductor layer 43, an active layer 50, a P-type cladding layer 60, a P-type semiconductor layer 70, a first electrode layer 80, and a second electrode layer 90.

The buffer layer 20 is stacked on the substrate 10. The substrate 10 is made of silicon (Si), and the buffer layer 20 can be formed in a stacked structure of AlInN/GaN, InₓGa₁₋ₓN/GaN, AlₓIn_{y}Ga_{1-x-y}N/InₓGa₁₋ₓN/GaN, and so on.

The buffer layer 20 functions to release stress between the substrate 10 and the semiconductor layer.

The substrate 10 including Si has a crystal structure different from that of the semiconductor layer including GaN. Hence, when the semiconductor layer is stacked on the substrate 10, lattice defects can occur.

The light emitting diode 100 according to an embodiment can reduce the propagation of dislocation caused by the lattice defects according to the structure of the N-type semiconductor layer that will be described below.

The undoped GaN layer 30 is formed on the buffer layer 20. The undoped GaN layer 30 is formed at a thickness of about 300 nm by supplying NH₃ of 4×10² mol/min and TMGa of 1×10⁻⁴ mol/min at a growth temperature of about 700° C.

At least one N-type semiconductor layer for supplying electrons to the active layer 50 is formed on the undoped GaN layer 30.

In the light emitting diode 100 according to an embodiment, the N-type semiconductor layer 40 includes the first semiconductor layer 41, the second semiconductor layer 42, and the third semiconductor layer 43.

The second semiconductor layer 42 is formed at a lower temperature, compared to the first and third semiconductor layers 41 and 43.

Further, the second semiconductor layer 42 is formed in the state where Si is not doped. However, if Si is doped, the second semiconductor layer 42 is formed at a lower doping concentration, compared to the first and third semiconductor layers 41 and 43.

First, the first semiconductor layer 41 can be formed of an N-type GaN layer doped with Si of a concentration of about 3×10¹⁸ dose/cm³ to about 7×10¹⁸ dose/cm³.

The first semiconductor layer 41 is formed at a thickness of about 2 μm to about 8 μm by supplying NH₃ of about 0.5 mol/min to about 5 mol/min, TMGa of about 0.5×10⁻³ mol/min to about 1.2×10⁻³ mol/min, and silane gas of about 2×10⁻⁹ mol/min to about 10×10⁻⁹ mol/min at a temperature of about 900° C. to about 1100° C.

The second semiconductor layer 42 is formed on the first semiconductor layer 41.

The second semiconductor layer 42 can be formed of a GaN layer that is not doped with Si, or is doped with Si at a lower concentration compared to the first semiconductor layer 41. For example, the second semiconductor layer 42 can be doped with Si of a concentration of about 5×10⁻¹⁷ dose/cm³ to about 6×10¹⁷ dose/cm³.

The second semiconductor layer 42 is formed at a thickness of about 0.1 μm to about 0.25 μm in a metal organic chemical vapor deposition (MOCVD) chamber or a molecular beam epitaxy (MBE) chamber by supplying NH₃ of about 0.1 mol/min to about 0.6 mol/min, TMGa of about 0.1×10⁻³ mol/min to about 0.3×10⁻³ mol/min, and silane gas of about 2×10⁻¹⁰ mol/min to about 2×10⁻⁹ mol/min at a temperature of about 450° C. to about 650° C.

Further, the second semiconductor layer 42 can be stacked using thin film crystal growth technology such as molecular beam epitaxy technology, or metal organic chemical vapor deposition technology, atomic layer epitaxy technology, and so on.

The second semiconductor layer 42 reduces vertical dislocations generated between the substrate 10 and the semiconductor layer.

The third semiconductor layer 43 is formed on the second semiconductor layer 42.

The third semiconductor layer 43 can be formed of an N-type GaN layer doped with Si of a concentration of about 3×10¹⁸ dose/cm³ to about 7×10¹⁸ dose/cm³.

The third semiconductor layer 43 is formed at a thickness of about 0.8 μm to about 1.5 μm by supplying NH₃ of about 0.5 mol/min to about 5 mol/min, TMGa of about 0.5×10⁻³ mol/min to about 1.2×10⁻³ mol/min, and silane gas of about 2×10⁻⁹ mol/min to about 10×10⁻⁹ mol/min at a temperature of about 900° C. to about 1100° C.

Meanwhile, the second semiconductor layer 42 is formed at a low temperature of about 450° C. to about 650° C., and thus has lower crystallinity compared to the first and third semiconductor layers 41 and 43.

Hence, when the third semiconductor layer 43 is formed on the second semiconductor layer 42 at a high temperature of about 900° C. to about 1100° C., the second semiconductor layer 42 is subjected to recrystallization.

While the second semiconductor layer 42 is being recrystallized, a horizontal lattice defect layer, in which numerous lattice defects such as vacancies and interstitial atoms occur in a horizontal direction, is formed at an interface between the second semiconductor layer 42 and the third semiconductor layer 43.

As illustrated in FIG. 1, the horizontal lattice defect layer causes the electrons to be widely distributed to move to the active layer 50 because the electrons are shifted through the horizontal lattice defects.

Thus, the light emitting diode 100 according to an embodiment can uniformly emit light throughout the active layer 50.

Further, the light emitting diode according to an embodiment has an effect that electrostatic discharge withstand voltage characteristics are reinforced as electric current flows through a wide area.

When the third semiconductor layer 43 is grown, the active layer 50, which includes InGaN/GaN and has a multi-quantum well (MOW), is formed using MOCVD.

The P-type cladding layer 60 is formed on the active layer 50.

The P-type cladding layer 60 is grown to a thickness of about 2 nm to about 50 nm at a temperature of about 830° C. to about 900° C., and can be grown by material such as aluminum gallium nitride (AlGaN).

The P-type cladding layer 60 has a band gap higher than that of the active layer 50, and increases inhibition of carriers between the active layer 50 and the P-type semiconductor layer 70 and the resulting luminous efficiency.

After the P-type cladding layer 60 is formed, the P-type semiconductor layer 70 is grown to a thickness of about 0.02 μm to about 0.1 μm by supplying TMGa of about 7×10⁻⁶ mol/min, trimethyl aluminum (TMAl) of about 2.6×10⁻⁵ mol/min, bis ethylcyclopentadienyl magnesium (EtCp2Mg) {Mg(C2H5C5H4)2} of about 5.2×10⁻⁷ mol/min, and NH₃ of about 2.2×10⁻¹ mol/min at an atmospheric temperature of about 1000° C. using hydrogen as carrier gas.

Subsequently, the P-type semiconductor layer 70 is subjected to, for instance, annealing at a temperature of about 950° C. for 5 minutes such that concentration of holes thereof reaches the maximum.

In this manner, when the stacked structure from the substrate 10 to the P-type semiconductor layer 70 is obtained, the stacked structure is subjected to wet or dry etching. Thereby, the P-type semiconductor layer 70, the P-type cladding layer 60, the active layer 50, and the third semiconductor layer 43 are partially removed.

For example, anisotropic wet etching is performed to expose part of the third semiconductor layer 43.

After the etching process is carried out, the first electrode layer 80 can be deposited with titan (Ti), and the second electrode layer 90 can be implemented as a transparent electrode, which is formed of at least one of ITO, ZnO, RuOx, TiOx and IrOx.

The light emitting diode 100 according to an embodiment is designed to stack the low crystallinity of second semiconductor layer 42 and the high crystallinity of third semiconductor layer 43 in the N-type semiconductor layer 40, and thus to form the horizontal lattice defect layer at the interface between the second and third semiconductor layers, thereby allowing the electric current to flow through the wide area.

Accordingly, the light is emitted from the wide area of the active layer 50, so that the luminous efficiency can be increased.

Further, because the electric current flows through the wide area, the electrostatic discharge withstand voltage can be improved.

In addition, the low crystallinity of second semiconductor layer 42 is formed, so that the propagation of the vertical dislocation can be blocked, and thus the quality of the active layer 50 can be improved.

In the embodiment, the description has been made focused on the light emitting diode of the horizontal structure. However, the light emitting diode according to another embodiment can be applied to one of the vertical structure including an N-type semiconductor layer, an active layer, a P-type semiconductor layer, a metal substrate, a first electrode layer, a second electrode layer, and so on.

In other words, the light emitting diode according to another embodiment can have a structure in which the metal substrate, the first electrode layer, the N-type semiconductor layer, the active layer, and the P-type semiconductor layer are vertically arranged. Further, unlike the embodiment illustrated in FIG. 1, the first electrode layer can be disposed under the N-type semiconductor layer.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting diode comprising:
an N-type semiconductor layer comprising a horizontal lattice defect layer;
an active layer on the N-type semiconductor layer; and
a P-type semiconductor layer on the active layer.

2. The light emitting diode as claimed in claim 1, wherein the N-type semiconductor layer comprises a first semiconductor layer, a second semiconductor layer, and a third semiconductor layer.

3. The light emitting diode as claimed in claim 2, wherein the second semiconductor layer has lower crystallinity, compared to the first semiconductor layer and the third semiconductor layer.

4. The light emitting diode as claimed in claim 2, wherein the second semiconductor layer is doped with less N type impurity, compared to the first semiconductor layer and the third semiconductor layer, or with no N-type impurity.

5. The light emitting diode as claimed in claim 4, wherein the N-type impurity includes Si.

6. The light emitting diode as claimed in claim 2, wherein the horizontal lattice defect layer is formed at an interface between the second semiconductor layer and the third semiconductor layer.

7. The light emitting diode as claimed in claim 1, comprising a first electrode layer that is on the N-type semiconductor layer by removing part of the N-type semiconductor layer.

8. The light emitting diode as claimed in claim 1, comprising a first electrode layer under the N-type semiconductor layer, and a second electrode layer on the P-type semiconductor layer.

9. A method of fabricating a light emitting diode, the method comprising:
forming an N-type semiconductor layer comprising a horizontal lattice defect layer;
forming an active layer on the N-type semiconductor layer; and
forming a P-type semiconductor layer on the active layer.

10. The method as claimed in claim 9, wherein the N-type semiconductor layer comprises a first semiconductor layer, a second semiconductor layer, and a third semiconductor layer.

11. The method as claimed in claim 10, wherein the second semiconductor layer has lower crystallinity, compared to the first semiconductor layer and the third semiconductor layer.

12. The method as claimed in claim 10, wherein the second semiconductor layer is formed at a lower temperature, compared to the first semiconductor layer and the third semiconductor layer.

13. The method as claimed in claim 12, wherein the second semiconductor layer is formed at a temperature of about 450° C. to about 650° C.

14. The method as claimed in claim 10, wherein the second semiconductor layer is doped with less N-type impurity, compared to the first semiconductor layer and the third semiconductor layer, or with no N-type impurity.

15. The method as claimed in claim 14, wherein the second semiconductor layer is doped with Si of a concentration of about 5×10¹⁷ dose/cm³ to about 6×10¹⁷ dose/cm³, and the third semiconductor layer is doped with Si of a concentration of about 3×10¹⁸ dose/cm³ to about 7×10¹⁸ dose/cm³.

16. The method as claimed in claim 10, wherein the horizontal lattice defect layer is formed at an interface between the second semiconductor layer and the third semiconductor layer.

17. The method as claimed in claim 10, wherein the first semiconductor layer is formed at a thickness of about 2 μm to about 8 μm by supplying NH₃ of about 0.5 mol/min to about 5 mol/min, TMGa of about 0.5×10⁻³ mol/min to about 1.2×10⁻³ mol/min, and silane gas of about 2×10⁻⁹ mol/min to about 10×10⁻⁹ mol/min at a temperature of about 900° C. to about 1100° C.

18. The method as claimed in claim 10, wherein the second semiconductor layer is formed at a thickness of about 0.1 μm to about 0.25 μm by supplying NH₃ of about 0.1 mol/min to about 0.6 mol/min, TMGa of about 0.1×10⁻³ mol/min to about 0.3×10⁻³ mol/min, and silane gas of about 2×10⁻¹⁰ mol/min to about 2×10⁻⁹ mol/min at a temperature of about 450° C. to about 650° C.

19. The method as claimed in claim 10, wherein the third semiconductor layer is formed at a thickness of about 0.5 μm to about 1.5 μm by supplying NH₃ of about 0.5 mol/min to about 5 mol/min, TMGa of about 0.5×10⁻³ mol/min to about 1.2×10⁻³ mol/min, and silane gas of about 2×10⁻⁹ mol/min to about 10×10⁻⁹ mol/min at a temperature of about 900° C. to about 1100° C.

20. The method as claimed in claim 9, wherein the horizontal lattice defect layer is formed on the second semiconductor layer as soon as the second semiconductor layer is recrystallized.
